(19) United States
(12) Patent Application Publication
(10) Pub. No.: US 2025/0259837 A1
(43) Pub. Date: Aug. 14, 2025

(54) RESPONSIVE LAYER FOR PHOTOLITHOGRAPHY FILM STACK

(71) Applicant: Applied Materials, Inc., Santa Clara, CA (US)

(72) Inventors: RUDY WOJTECKI, East Garrison, CA (US); ZEQING SHEN, San Jose, CA (US); ABHIJIT MALLICK, Fremont, CA (US); ZHIYU HUANG, Sunnyvale, CA (US); MADHUR SACHAN, Belmont, CA (US); SIVANANDHA KANAKASABAPATHY, Pleasanton, CA (US)

(21) Appl. No.: 19/019,209

(22) Filed: Jan. 13, 2025

Related U.S. Application Data
(60) Provisional application No. 63/552,009, filed on Feb. 9, 2024.
(60) Provisional application No. 63/712,322, filed on Oct. 25, 2024.

(51) Int. Cl. H01L 21/02; H01L 21/027

(52) U.S. Cl. CPC H01L 21/02274; H01L 21/02118; H01L 21/0228; H01L 21/02282; H01L 21/0274

(57) ABSTRACT

Embodiments described herein relate to a method for patterning a patterning stack that includes forming the patterning stack over a substrate, where the patterning stack includes a responsive layer and a resist layer over the responsive layer. In an embodiment, the responsive layer is deposited with a plasma enhanced chemical vapor deposition (PECVD) process with a temperature less than 250° C. In an embodiment, the process further includes forming an opening in the resist layer, and transferring a pattern of the opening into the responsive layer. In an embodiment, the responsive layer has a first line width roughness (LWR). In an embodiment, the method further includes reflowing the responsive layer to form a reflown responsive layer, where the reflown responsive layer has a second LWR that is smaller than the first LWR.

### CROSS-REFERENCE TO RELATED APPLICATIONS

This application claims the benefit of U.S. Provisional Application No. 63/552,009, filed on Feb. 9, 2024, the entire contents of which are hereby incorporated by reference herein. This application claims the benefit of U.S. Provisional Application No. 63/712,322, filed on Oct. 25, 2024, the entire contents of which are hereby incorporated by reference herein.

### BACKGROUND

### 1) FIELD

Embodiments relate to the field of semiconductor manufacturing and, in particular, apparatuses and methods for using a responsive layer in an extreme ultraviolet (EUV) patterning stack for improved line width roughness (LWR) and line edge roughness (LER).

### 2) DESCRIPTION OF RELATED ART

Semiconductor devices are continuously scaling to smaller feature sizes. Improvements in lithography systems are needed in order to keep up with shrinking features. For example, extreme ultraviolet (EUV) lithography has been used in order to enable the printing of smaller features. Unfortunately, EUV resists suffer from poor absorption of the EUV radiation. That is, the chemical structure within the EUV resist does not easily react in the presence of the EUV radiation in order to generate the necessary solubility switch. Accordingly, larger doses of EUV radiation are needed in order to obtain the desired contrast in the resist layer.

Increasing the dose causes an increase in the exposure time. This reduces the throughput of the system and increases the cost of EUV lithography. Some tradeoffs can be made in order to reduce the necessary dose. For example, a lower dose of EUV radiation may be used at the expense of line edge roughness (LER) and/or line width roughness (LWR). High LER and LWR can negatively impact pattern transfer, and may not be desirable for all patterning processes.

### SUMMARY

Embodiments described herein relate to a method for patterning a patterning stack that includes forming the patterning stack over a substrate, where the patterning stack includes a responsive layer and a resist layer over the responsive layer. In an embodiment, the responsive layer is deposited with a plasma enhanced chemical vapor deposition (PECVD) process with a temperature less than 250° C. In an embodiment, the process further includes forming an opening in the resist layer, and transferring a pattern of the opening into the responsive layer. In an embodiment, the responsive layer has a first line width roughness (LWR). In an embodiment, the method further includes reflowing the responsive layer to form a reflown responsive layer, where the reflown responsive layer has a second LWR that is smaller than the first LWR.

Embodiments described herein relate to a method for patterning a patterning stack that includes forming the patterning stack over a substrate, where the patterning stack includes a responsive layer and a resist layer over the responsive layer. In an embodiment, the responsive layer is deposited with a spin coating process. The process may also include forming an opening in the resist layer, and transferring a pattern of the opening into the responsive layer, where the responsive layer has a first line width roughness (LWR). In an embodiment, the process may further include reflowing the responsive layer to form a reflown responsive layer, where the reflown responsive layer has a second LWR that is smaller than the first LWR.

### BRIEF DESCRIPTION OF THE DRAWINGS

FIG. 1 is a cross-sectional illustration of a substrate with a patterned resist layer that includes poor line edge roughness (LER) and poor line width roughness (LWR), in accordance with an embodiment.

FIG. 2 is a graph of exposure dose versus LER and illustrates that higher exposure doses result in improved LER, in accordance with an embodiment.

FIG. 3A is a cross-sectional illustration of a substrate with a patterning stack that comprises a responsive layer under a resist, in accordance with an embodiment.

FIG. 3B is a cross-sectional illustration of a substrate with a patterning stack that comprises a responsive layer under a resist with an underlayer between the responsive layer and the resist, in accordance with an embodiment.

FIGS. 4A-4E are cross-sectional illustrations depicting a process for patterning a substrate with a patterning stack that comprises a modifiable responsive layer, in accordance with an embodiment.

FIGS. 5A-5C are cross-sectional illustrations depicting a process for patterning a substrate with a patterning stack that comprises a modifiable responsive layer, in accordance with an additional embodiment.

FIG. 6 is a diagram of chemistries that may be used to form a disulfide layer that can be used for the responsive layer, in accordance with an embodiment.

FIG. 7 is a process flow diagram of a process for patterning a substrate with a patterning stack that comprises a modifiable responsive layer that exhibits a decrease in LER when exposed to a stimulus treatment, in accordance with an embodiment.

FIG. 8 illustrates a block diagram of an exemplary computer system that may be used in conjunction with a processing tool, in accordance with an embodiment.

### DETAILED DESCRIPTION

Embodiments described herein include apparatuses and methods for using a responsive layer in an extreme ultraviolet (EUV) patterning stack for improved line width roughness (LWR) and line edge roughness (LER). In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

In EUV lithography, a resist that is chemically reactive to EUV radiation is deposited over a substrate. The EUV resist may include a metal-oxide (e.g., tin-oxide) material, or a chemically amplified resist (CAR) system. Once deposited, the resist is selectively exposed with EUV radiation through the use of a mask and/or reticle. The EUV radiation initiates a chemical reaction within the resist. The chemical reaction may result in a solubility change of the exposed regions of the resist. The exposed resist may sometimes be considered as having a latent image of the desired pattern. After exposure, a developing process may be used to selectively remove the exposed regions relative to the unexposed regions, or the unexposed regions may be selectively removed relative to the exposed regions (depending on if the resist is a positive tone resist or a negative tone resist).

The pattern formed within the resist may then be transferred into an underlying patterning stack. However, the surface features of the pattern in the resist may be transferred into underlying layers as well. Accordingly, if the resist is not patterned with straight sidewalls (e.g., a low LER or a low LWR), the undesirable topography of the sidewalls will be transferred into the underlying layers.

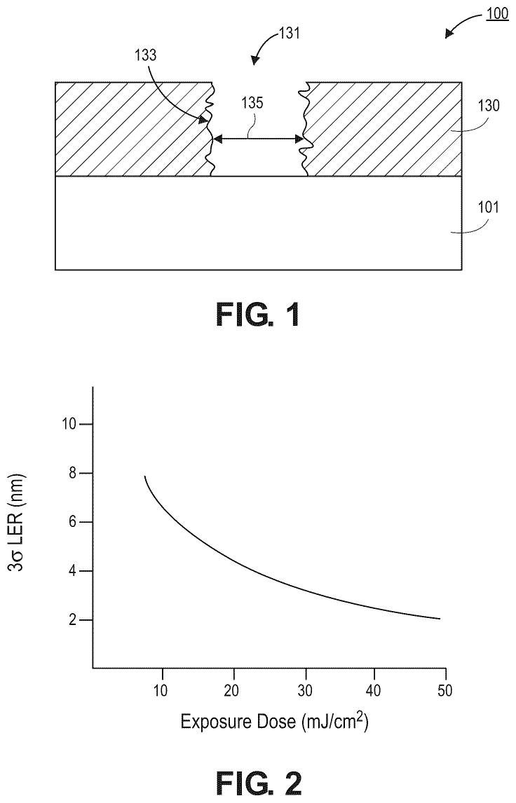

Typically, EUV lithography systems suffer from low absorption of the EUV radiation in the resist. A consequence of the low absorption is that the edges of the patterned resist have high LER and high LWR. An example of a device 100 with a patterned resist layer 130 is shown in FIG. 1. FIG. 1 is a cross-sectional illustration of a substrate 101 with a resist layer 130 over the substrate 101. The substrate 101 may be any type of substrate (e.g., silicon wafer, or the like). While the resist layer 130 is shown as being directly on the substrate 101, other embodiments may include one or more intervening layers between the substrate 101 and the resist layer 130. For example, a patterning stack similar to any of the patterning stacks described in greater detail below may be provided between the substrate 101 and the resist layer 130.

In an embodiment, the resist layer 130 may be an EUV resist material, such as a metal-oxide based material or a CAR. While an EUV resist is described in detail herein, it is to be appreciated that other resist materials and lithography regimes may also suffer from similar absorption issues. That is, the term “resist layer” or “resist” may comprise any type of resist material, such as those compatible with EUV radiation, deep ultraviolet (DUV) radiation, or any other wavelength or wavelengths of electromagnetic radiation suitable for photolithography processes. In an embodiment, the resist layer 130 may have been exposed and developed with a process similar to the process described in greater detail above. As such, an opening 131 (sometimes also referred to as a trench, a hole, or a pattern) may pass through a thickness of the resist layer 130. The opening 131 may have sidewalls 133. As shown, the sidewalls 133 have a non-linear and irregular profile. That is, the LER of the sidewalls 133 is relatively high. Similarly the LWR 135 (i.e., the variation of the width of the opening 131 through the thickness of the resist layer 130) is high. These traits can lead to poor pattern transfer into the underlying substrate 101.

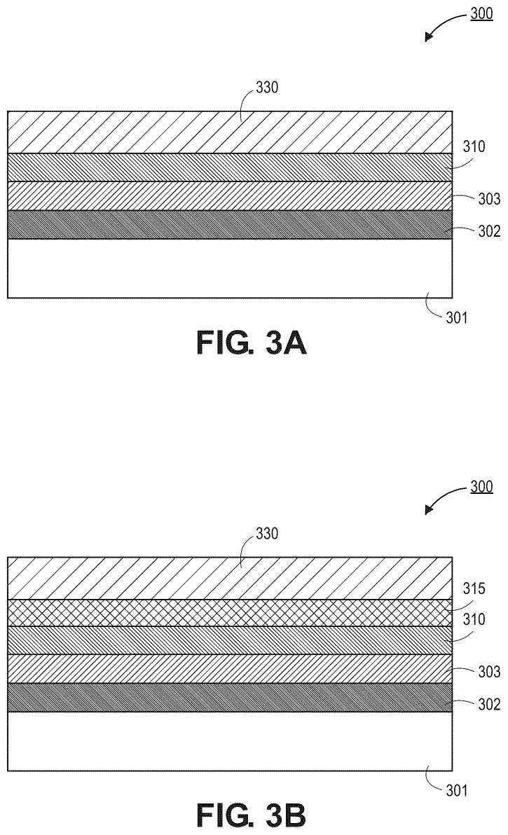

The LER and/or LWR can be improved by increasing the dose of the exposure during the lithographic exposure process. However, increasing the dose requires a longer exposure duration. This can lead to a lower throughput and/or a higher cost of the EUV lithography process. FIG. 2 is a graph that shows the general relationship between the exposure dose (x-axis) and the LER (y-axis). Lower LER is associated with improved patterning performance. As shown, increasing the dose can provide an improvement (i.e., decrease) in the LER. The improvement can be significant in some embodiments. For example, a LER of around 8 nm can be decreased to around 2 nm when the dose is significantly increased.

Ideally, a reduction in LER and LWR is obtained without needing to increase the dose. This allows for improved throughput without sacrificing patterning performance. Previous research has been focused on improving the chemistry of the resist layer in order to provide such results. However, embodiments disclosed herein use a modifiable responsive layer below the resist in order to improve the LER and LWR. The responsive layer is formed from a material that is capable of “reflow” in response to a stimulus. As such, the responsive layer may be patterned and have a first LER/LWR similar to that of the resist layer. A stimulus (e.g., thermal, electromagnetic radiation, or chemical) is then applied to the responsive layer to initiate the reflow in order to produce a second LER/LWR that is smaller than the first LER/LWR.

As used herein “reflow” may refer to several different processes. In one embodiment, reflow may refer to bringing a material above a glass transition temperature of the material or a melting point of the material. In this state, the material can flow (similar to a fluid). In other embodiments, reflow may refer to a chemical process that includes cross-linking and/or rearrangement of chemical bonds within the material. Generally, reflowing the responsive layer may allow for changes to the topography of the surfaces of the material in order to decrease the surface energy of the responsive layer.

In an embodiment, the responsive layer may also provide functionality of an underlayer. For example, the responsive layer may be a source of secondary electron generation and/or the generation of radicals or other chemical species that diffuse into the resist layer during exposure. The secondary electrons and chemical species may improve the patterning performance of the resist layer. In other embodiments, the responsive layer may be a different layer than the underlayer. In such an embodiment, both the underlayer and the responsive layer may be tuned to perform optimally for their specific purpose.

In an embodiment, responsive layers disclosed herein may comprise many different material systems. Generally, the material systems for the responsive layer comprise materials that can undergo a reflow in response to a treatment stimulus. In some embodiments, the responsive layer may be an organic material. For example, the responsive layer may comprise one or more of polymethyl methacrylate (PMMA), polystyrene (PS), Nylon 12, or polydimethylglutarimide (PMGI), parylene, or the like. More generally, responsive layers may comprise linear polymers with reflow behavior or polymer networks with reversible chemistry (e.g., reversible crosslinking or supramolecular crosslinking). In other embodiments, the responsive layer may be an inorganic material. For example, the responsive layer may comprise one or more of tin, bismuth, indium, or selenium. More generally, inorganic materials may be materials with reflow behavior at low temperatures (e.g., low melting temperatures). Other embodiments comprise polymers with disulfide bonds. For example, a polyurethane with disulfide bonds may be used in some embodiments.

In an embodiment, the responsive layers may be deposited with various different deposition processes. For example, dry deposition processes, such as chemical vapor deposition (CVD), plasma enhanced CVD (PE-CVD), atomic layer deposition (ALD), plasma enhanced ALD (PE-ALD), physical vapor deposition (PVD), or the like may be used in some embodiments. Dry processes may also comprise molecular layer deposition (MLD) processes. In an embodiment, wet processes, such as spin-coating, may be used in order to deposit the responsive layer.

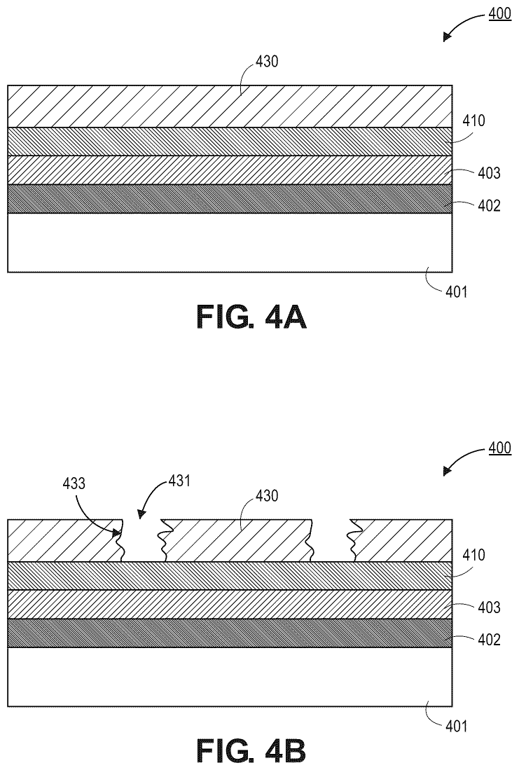

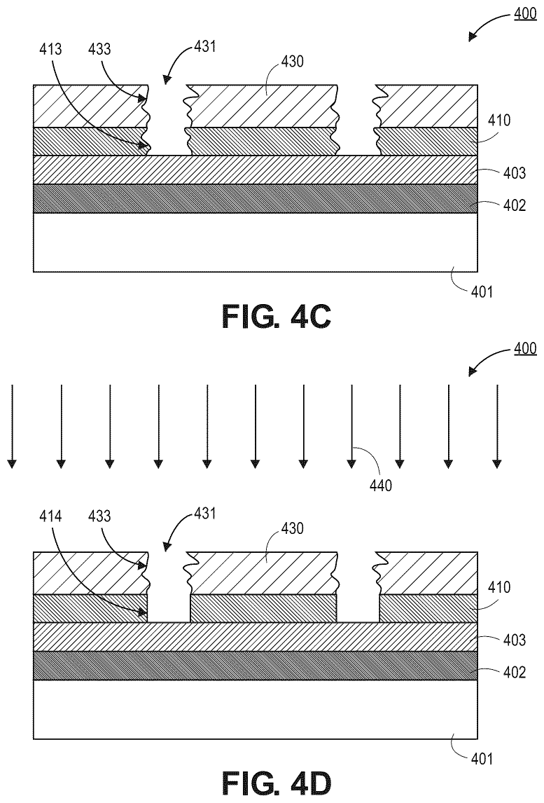

Referring now to FIG. 3A, a cross-sectional illustration of a device 300 is shown, in accordance with an embodiment. In an embodiment, the device 300 may comprise a substrate 301. The substrate 301 may be a semiconductor substrate, such as a silicon wafer. Though, other semiconductor materials, ceramics, glasses, or the like may also be used for the substrate 301. The substrate 301 may also have a form factor other than a form factor of a wafer.

In an embodiment, a patterning stack is provided over the substrate 301. In an embodiment, the patterning stack may comprise a carbon containing layer 302. The carbon containing layer 302 may be a spin-on-carbon (SOC) material. In an embodiment, a hardmask 303 may be provided over the carbon containing layer 302. In an embodiment, the hardmask 303 may comprise any suitable material, such as an organic hardmask, an inorganic hardmask, or the like. For example, the hardmask 303 may comprise silicon, nitrogen, metallic elements, oxygen, carbon, or any other suitable element for hardmask 303 development.

In an embodiment, a responsive layer 310 is provided over the hardmask 303. The responsive layer 310 may be a material that is capable of being reflown in response to a stimulus. For example, the stimulus may comprise a thermal stimulus, an electromagnetic radiation stimulus (e.g., light, UV light, etc.), or a chemical stimulus. As will be described in greater detail below, the responsive layer 310 may be patterned. The responsive layer 310 is then treated with the stimulus in order to reduce a LER and/or LWR of the patterned surfaces of the responsive layer 310.

In an embodiment, the responsive layer 310 may comprise an organic material. For example, the responsive layer 310 may comprise linear polymers with reflow behavior, or polymer networks with reversible chemistry (e.g., reversible crosslinking or supramolecular crosslinking). For example, the responsive layer 310 may comprise one or more of PMMA, PS, Nylon 12, or PMGI. Such polymeric materials may be deposited with a spin-on process, CVD processes, such as a plasma enhanced CVD (PECVD) process, or ALD processes. Though, other deposition processes may also be used in some embodiments.

In another embodiment, the responsive layer 310 may comprise an inorganic material. For example, the responsive layer 310 may comprise one or more of tin, bismuth, indium, or selenium. More generally, inorganic materials may be materials with reflow behavior at low temperatures (e.g., low melting temperatures). Inorganic materials may be deposited with PVD processes, CVD processes or ALD processes. Though, other deposition processes may also be used in some embodiments.

Other embodiments comprise a responsive layer 310 that comprise polymers with disulfide bonds. For example, a polyurethane with disulfide bonds may be used in some embodiments. The use of disulfide bonds allows for the responsive layer 310 to reflow in a controllable manner in response to a given stimulus (e.g., heat or light). Such disulfide based polymers may be deposited with an MLD process. Though, other deposition processes may also be used in some embodiments.

In yet another embodiment, the responsive layer 310 may comprise a polymeric material with relatively long carbon chains with light crosslinking. In some instances the responsive layer 310 may include high EUV absorbing heteroatoms in the monomers in order to improve the reaction to EUV radiation. Such an embodiment may allow for further reduction in the necessary dose for overlying resist layer 330. In some instances, such a linear polymer chain may be deposited with a PECVD process that includes one or more of a low power, low temperature, and/or a pulsed plasma. Such a polymer may also be deposited with a spin coating process. In some embodiments, the polymer may be a low-k dielectric polymer material. A more detailed description of such linear chain polymers is described in greater detail herein.

In some embodiments, the reflow of the responsive layer is implemented at a low temperature that is compatible with the rest of the patterning stack. For example, the resist layer 330 is often damaged (e.g., melts or reflows) at low temperatures. As such, reflow temperatures may be provided up to approximately 250° C. in some instances. Stimulus options other than heat (e.g., chemical and light) can also be used in order to protect the rest of the patterning stack from elevated temperatures.

In the embodiment shown in FIG. 3A, the responsive layer 310 may also function as an underlayer. That is, the responsive layer 310 may play an active role in the chemical transformation of the exposed regions of the resist layer 330 during the lithographic exposure. For example, the responsive layer 310 may be a source of secondary electrons and/or chemical species or radicals that diffuse into the resist layer 330. These electrons and species can improve the rate of chemical reaction within the resist layer 330 in order to lower the necessary dose, improve contrast, and/or otherwise improve patterning performance.

In an embodiment, the resist layer 330 is provided over the responsive layer 310. The resist layer 330 may be any suitable photosensitive material that is compatible with a given lithography process. An EUV resist layer 330 is described in detail herein. However, it is to be appreciated that the resist layer 330 may also be a deep ultraviolet (DUV) resist layer 330, or a resist layer 330 compatible with any other wavelength or wavelengths of electromagnetic radiation. In a particular embodiment, the resist layer 330 may comprise a metal-oxide material composition. For example, the resist layer 330 may comprise a tin-oxide material system. In other embodiments, the resist layer 330 may comprise a CAR material system.

The resist layer 330 may be deposited over the responsive layer 310 with any suitable process. In one embodiment, the resist layer 330 is deposited with a spin-on process. In other embodiments, the resist layer 330 is deposited with a dry deposition process, such as a CVD process, a PECVD process, an ALD process, a PEALD process, or the like. In a dry deposition process, the composition of the resist layer 330 may be varied through a thickness of the resist layer 330. For example, a bottom of the resist layer 330 may be tuned for adhesion, and the rest of the resist layer 330 may be tuned for sensitivity to EUV radiation.

Referring now to FIG. 3B, a cross-sectional illustration of a device 300 is shown, in accordance with an additional embodiment. In an embodiment, the device 300 in FIG. 3B may be similar to the device 300 in FIG. 3A, with the addition of an underlayer 315. The underlayer 315 may be provided between the responsive layer 310 and the resist layer 330. The underlayer 315 may comprise any suitable underlayer material composition. For example, the underlayer 315 may comprise one or more of silicon, carbon, oxygen, or hydrogen. Other elements may also be integrated into the underlayer 315 in different embodiments. The underlayer 315 may be tuned to improve the patterning performance of the resist layer 330. For example, a chemical structure of the underlayer 315 may generate more secondary electrons, radicals, and/or other chemical species that can diffuse into the resist layer 330 during EUV exposure.

Separating the underlayer 315 from the responsive layer 310 allows for improved optimization of both layers. Since the responsive layer 310 no longer needs to participate in the exposure process, the responsive layer 310 can be designed for improved reflow performance. Improved reflow performance may include the ability to reflow with a smaller stimulus (e.g., lower temperatures, lower light flux, smaller concentration of chemistries, etc.), and/or greater reductions in LER and/or LWR.

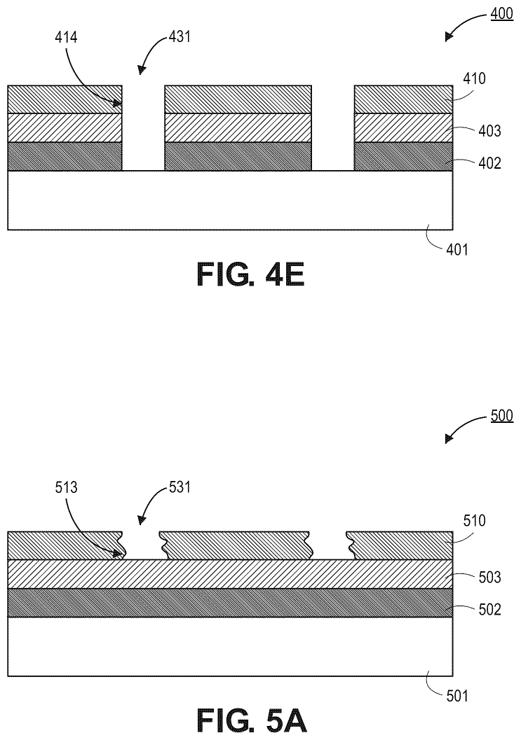

Referring now to FIGS. 4A-4E, a series of cross-sectional illustrations depicting a process for patterning a patterning stack with improved LER and/or LWR is shown, in accordance with an embodiment. In an embodiment, the device 400 in FIGS. 4A-4E has a patterning stack that is similar to the patterning stack of device 300 in FIG. 3A. Though, it is to be appreciated that patterning stacks similar to any of those described in greater detail herein may be patterned with similar processes in accordance with various embodiments.

Referring now to FIG. 4A, a cross-sectional illustration of a device 400 is shown, in accordance with an embodiment. In an embodiment, the device 400 may comprise a substrate 401. The substrate 401 may be similar to the substrate 301 described in greater detail above. Similarly, carbon containing layer 402 and hardmask 403 may be similar to the carbon containing layer 302 and the hardmask 303 described in greater detail above.

In an embodiment, a responsive layer 410 is provided over the hardmask 403. The responsive layer 410 may be similar to any of the responsive layers described in greater detail herein. For example, the responsive layer 410 may be a material that is responsive to a stimulus. That is, the application of a stimulus (e.g., heat, light, chemicals) may result in the responsive layer 410 reflowing in order to reduce a LER and/or a LWR. Generally, the responsive layer 410 may be an organic material, an inorganic material, or a disulfide based material. The responsive layer 410 may be deposited over the hardmask 403 with a spin-coating process or a dry deposition process (e.g., CVD, PE-CVD, ALD, PE-ALD, PVD, MLD, etc.).

In an embodiment a resist layer 430 is provided over the responsive layer 410. The resist layer 430 may comprise an EUV resist material or the like. For example, the resist layer 430 may comprise a metal-oxide resist or a CAR. The resist layer 430 may be applied with a dry deposition process or a spin-coating process. The resist layer 430 may be similar to any of the resist layers described in greater detail herein.

Referring now to FIG. 4B, a cross-sectional illustration of the device 400 after an exposure and developing process has been performed is shown, in accordance with an embodiment. In an embodiment, the resist layer 430 is selectively exposed with EUV radiation (or other suitable electromagnetic radiation) through the use of a mask and/or reticle (not shown). The EUV radiation initiates a chemical reaction within the resist layer 430. The chemical reaction may result in a solubility change of the exposed regions of the resist layer 430 in order to form a latent image of the desired pattern.

In some embodiments, the exposure to EUV radiation may also result in the formation of species, chemistries, and/or compounds within the responsive layer 410. Such species, chemistries, and/or compounds may diffuse into the overlying resist layer 430 in order to participate in the chemical reaction that provides the solubility change within the exposed regions of the resist layer 430. That is, the responsive layer 410 may provide functionality similar to a typical underlayer for EUV lithography. It has been shown that such, species diffusion from the responsive layer 410 to the resist layer 430 provides particularly beneficial results (e.g., providing improvements with respect to the dose-to-size) when used with a MOR resist layer 430 and/or with a PECVD deposited responsive layer 410. For example, EUV exposure of the responsive layer 410 may produce highly reactive radical anions that may abstract protons from neighbors, thus decomposing into CO₂, methyl formate and methanol. In an embodiment, the released chemistries may promote cross-linking of the metal clusters (e.g., tin clusters) in the overlying MORE resist layer 430.

After exposure, a developing process (e.g., an etching process) may be used to selectively remove the exposed regions relative to the unexposed regions, or the unexposed regions may be selectively removed relative to the exposed regions (depending on if the resist is a positive tone resist or a negative tone resist). As shown, the developing process may result in the formation of openings 431 through the resist layer 430. The openings 431 may be holes, trenches, or any other desired pattern that passes through a thickness of the resist layer 430.

In an embodiment, the openings 431 may have sidewalls 433. As illustrated, the sidewalls 433 may have a relatively high LER and LWR. This may be due (at least in part) to the use of a low dosage exposure for the resist layer 430. For example, the dosage of the exposure may be approximately 30 mJ/cm² or lower, or approximately 15 mJ/cm² or lower. Though, any dose may benefit from embodiments disclosed herein.

Referring now to FIG. 4C, a cross-sectional illustration of the device 400 after the pattern of the openings 431 is transferred into the underlying responsive layer 410 is shown, in accordance with an embodiment. In an embodiment, the pattern may be transferred with an etching process. The etching process may be a wet etch or a dry etch. As shown, the openings 431 continue into the responsive layer 410 and include sidewalls 413. Similar to the sidewalls 433, the sidewalls 413 may comprise a high LER and LWR. This is due to the pattern transfer from the resist layer 430 to the responsive layer 410.

Referring now to FIG. 4D, a cross-sectional illustration of the device after a stimulus treatment process is shown, in accordance with an embodiment. As shown a stimulus 440 is applied to the device 400. The stimulus 440 initiates a reflow of the responsive layer 410. While in a reflow state, the responsive layer 410 is able to adjust free surfaces (e.g., sidewalls 414) in order to minimize surface energy. Accordingly, the high LER and LWR of the sidewall 413 in FIG. 4C is reduced in FIG. 4D. The improved LER and LWR of the of the sidewall 414 in the modified responsive layer 410 can be used in order to provide improved patterning in the underlying layers without needing higher exposure dosages. This reduces costs and improves throughput without sacrificing performance.

The stimulus 440 may comprise a thermal stimulus. For example, the stimulus 440 may be applied by thermal lamps in an annealing chamber or the like. A hot-plate, a heated pedestal, a heated electrostatic chuck (ESC), or the like may also be used to apply thermal energy to the device 400. A laser May also apply the necessary thermal energy in some embodiments. The thermal energy may allow for the responsive layer 410 to reflow due to the material exceeding a glass transition temperature or a melting temperature.

The stimulus 440 may also comprise an electromagnetic radiation exposure (e.g., UV radiation, visible light, etc.). Such a stimulus 440 may be more controllable than other solutions. For example, a light source may be provided over the device 400, and the light source can provide a desired dose of the light in order to obtain the desired effect. Light exposure may allow for reflow through an increase in the flowability of the material, change in a chemical structure (e.g., reversible cross-linking, supramolecular cross-linking, etc.).

The stimulus 440 may also comprise a chemical stimulus 440. A chemical stimulus 440 may be applied through the injection of a chemical reagent into a chamber that triggers a reflow behavior. For example, chambers suitable for CVD or ALD processes may be used in order to apply the chemical reagents of the stimulus 440 to the responsive layer 410.

Referring now to FIG. 4E, a cross-sectional illustration of the device 400 after the resist layer 430 is stripped is shown, in accordance with an embodiment. As shown, the responsive layer 410 is now the uppermost layer, and sets the pattern for the openings 431. Due to the low LER and LWR of the sidewalls 414, subsequent pattern transfer into the hardmask 403 and the carbon containing layer 402 will also result in low LER and LWR features. The pattern of the openings 431 may be passed into the hardmask 403 and the carbon containing layer 402 with any suitable etching process. After the patterning stack is fully patterned, an etching process may be used to pattern the underlying substrate 401. The etching of the substrate 401 may include a dry etching process, a wet etching process, or the like.

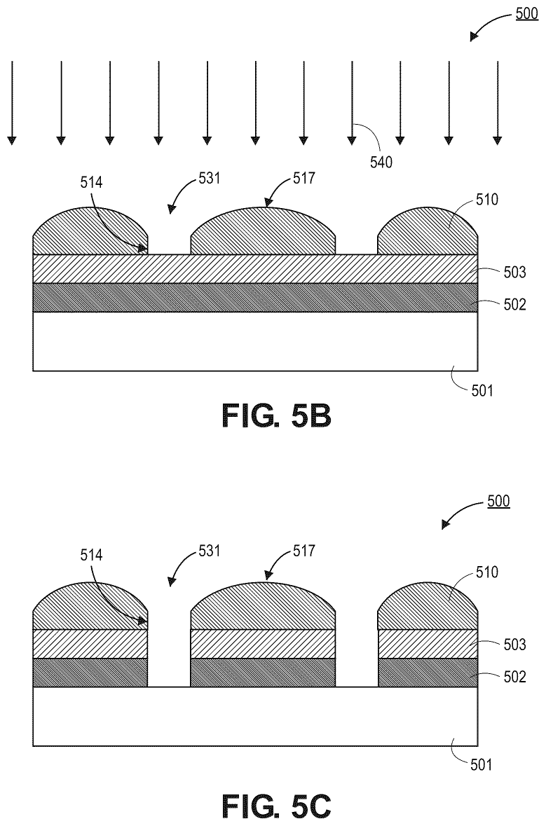

Referring now to FIGS. 5A-5C, a series of cross-sectional illustrations depicting a process for reflowing a responsive layer 510 to reduce LER and LWR is shown, in accordance with an embodiment. In an embodiment, the process depicted in FIGS. 5A-5C may be similar to the process depicted in FIGS. 4A-4E with the exception of when the resist layer is stripped.

Referring now to FIG. 5A, a cross-sectional illustration of a device 500 is shown, in accordance with an embodiment. In an embodiment, the device 500 may comprise a substrate 501. The substrate 501 may be similar to the substrate 301 described in greater detail above. Similarly, carbon containing layer 502 and hardmask 503 may be similar to the carbon containing layer 302 and the hardmask 303 described in greater detail above.

In an embodiment, a responsive layer 510 is provided over the hardmask 503. The responsive layer 510 may be similar to any of the responsive layers described in greater detail herein. For example, the responsive layer 510 may be a material that is responsive to a stimulus. That is, the application of a stimulus (e.g., heat, light, chemicals) may result in the responsive layer 510 reflowing in order to reduce a LER and/or a LWR. Generally, the responsive layer 510 may be an organic material, an inorganic material, or a disulfide based material. The responsive layer 510 may be deposited over the hardmask 503 with a spin-coating process or a dry deposition process (e.g., CVD, PE-CVD, ALD, PE-ALD, PVD, MLD, etc.).

As shown in FIG. 5A, the responsive layer 510 has been patterned to form openings 531. The patterning process to form the openings 531 may be similar to the processing operations described above with respect to FIGS. 4A - 4C. As shown, the openings 531 may have sidewalls 513 that have high LER and LWR. This is due to the overlying resist layer (not shown in FIG. 5A) being exposed with a low dose so that the resist layer has high LER and LWR sidewalls. However, instead of leaving the resist layer over the patterned responsive layer 510 during stimulus treatment, the resist layer is stripped. Stripping the resist layer may allow for the stimulus to have easier access to the responsive layer 510.

Referring now to FIG. 5B, a cross-sectional illustration of the device 500 during a stimulus 540 treatment is shown, in accordance with an embodiment. As shown a stimulus 540 is applied to the device 500. The stimulus 540 initiates a reflow of the responsive layer 510. While in a reflow state, the responsive layer 510 is able to adjust free surfaces (e.g., sidewalls 514 and top surface 517) in order to minimize surface energy. Accordingly, the high LER and LWR of the sidewall 513 in FIG. 5A is reduced in FIG. 5B. The improved LER and LWR of the of the sidewall 514 of the modified responsive layer 510 can be used in order to provide improved patterning in the underlying layers without needing higher exposure dosages. This reduces costs and improves throughput without sacrificing performance. Further, since there is no structure over the top surface 517 of the responsive layer 510, a curved surface may be generated in order to reduce surface energy.

The stimulus 540 may comprise a thermal stimulus. For example, the stimulus 540 may be applied by thermal lamps in an annealing chamber or the like. A hot-plate, a heated pedestal, a heated ESC, or the like may also be used to apply thermal energy to the device 500. A laser may also apply the necessary thermal energy in some embodiments. The thermal energy may allow for the responsive layer 510 to reflow due to the material exceeding a glass transition temperature or a melting temperature.

The stimulus 540 may also comprise an electromagnetic radiation exposure (e.g., UV radiation, visible light, etc.). Such a stimulus 540 may be more controllable than other solutions. For example, a light source may be provided over the device 500, and the light source can provide a desired dose of the light in order to obtain the desired effect. Light exposure may allow for reflow through an increase in the flowability of the material, change in a chemical structure (e.g., reversible cross-linking, supramolecular cross-linking, etc.).

The stimulus 540 may also comprise a chemical stimulus 540. A chemical stimulus 540 may be applied through the injection of a chemical reagent into a chamber that triggers a reflow behavior. For example, chambers suitable for CVD or ALD processes may be used in order to apply the chemical reagents of the stimulus 540 to the responsive layer 510.

Referring now to FIG. 5C, a cross-sectional illustration of the device 500 after the pattern is transferred into the remainder of the patterning stack is shown, in accordance with an embodiment. Due to the low LER and LWR of the sidewalls 514, subsequent pattern transfer into the hardmask 503 and the carbon containing layer 502 will also result in low LER and LWR features. The pattern of the openings 531 may be passed into the hardmask 503 and the carbon containing layer 502 with any suitable etching process. After the patterning stack is fully patterned, an etching process may be used to pattern the underlying substrate 501. The etching of the substrate 501 may include a dry etching process, a wet etching process, or the like.

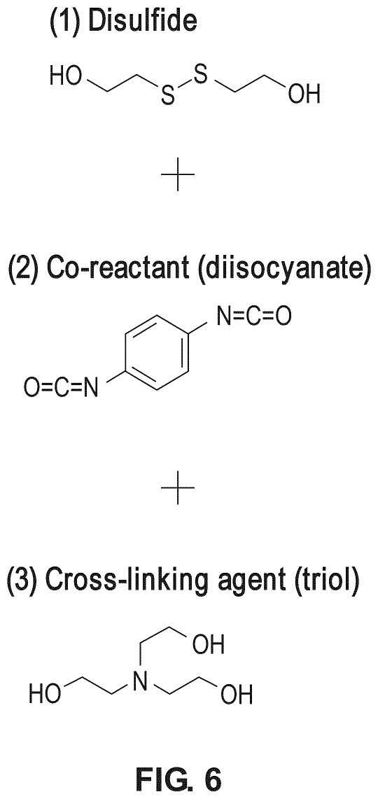

Referring now to FIG. 6, a chemical diagram of the formation of a material comprising disulfide bonds is shown, in accordance with an embodiment. As shown, a disulfide (1) is added to a co-reactant (2) and a cross-linking agent (3). In an embodiment, the co-reactant may comprise a diisocyanate and the cross-linking agent may comprise a triol. Though, it is to be appreciated that other chemical structures that allow for suitable disulfide bonds that enable reflow may be used in accordance with embodiments described herein. In some embodiments, the disulfide structure may be integrated into an organic polymer, such as a polyurethane or the like. In an embodiment, disulfide bond materials may be deposited with an MLD process, a CVD process, an ALD process, or the like.

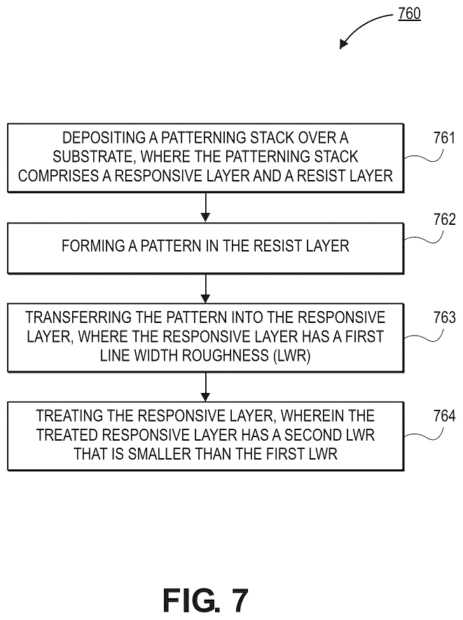

Referring now to FIG. 7, a process flow diagram of a process 760 for improving LER and/or LWR in a patterning stack is shown, in accordance with an embodiment. In an embodiment, the process 760 may begin with operation 761, which comprises depositing a patterning stack over a substrate. In an embodiment, the patterning stack comprises a responsive layer and a resist layer. For example, the patterning stack may be similar to any of the patterning stacks described in greater detail herein. The responsive layer may be a material that is capable of reflowing upon treatment with a stimulus, such as a thermal stimulus, a light stimulus, or a chemical stimulus. The responsive layer may be similar to any of the responsive layers described in greater detail herein. The resist layer may also be similar to any of the resist layers described in greater detail herein. For example, the resist layer may be an EUV resist material.

In an embodiment, the process may continue with operation 762, which comprises forming a pattern in the resist layer. The pattern in the resist layer may be formed by exposing the resist layer with electromagnetic radiation that drives a chemical reaction in the resist layer. In an embodiment, the exposure may be considered a relatively low dose exposure. For example, an exposure dose may be approximately 30 mJ/cm² or lower, or approximately 15 mJ/cm² or lower. Though, any dose may benefit from embodiments disclosed herein. After a latent image is formed in the resist layer, a developing process may form openings, trenches, or the like through the resist layer.

In an embodiment, the process may continue with operation 763, which comprises transferring the pattern into the responsive layer. In an embodiment, the responsive layer has a first LWR and/or a first LER. The first LWR and the first LER may be relatively high, due to the low dose of the resist layer exposure.

In an embodiment, the process may continue with operation 764, which comprises treating the responsive layer. In an embodiment, the treated responsive layer has a second LWR and/or a second LER that is smaller than the first LWR and/or the first LER. The treatment may be the application of a stimulus (e.g., a thermal stimulus, a light based stimulus, or a chemical stimulus) that causes the responsive layer to reflow. The reflowing responsive layer rearranges the surface profile in order to minimize a surface energy of the responsive layer. This results in a more linear surface with a smaller LWR and LER.

After the responsive layer is reflown to reduce LWR and LER, the pattern in the responsive layer can be transferred into the rest of the patterning stack. The underlying substrate can then be patterned with a suitable etching process. In this manner, highly accurate, precise, and repeatable patterning can be provided on a device using EUV lithography with low exposure dosages. This reduces the cost of the lithography process and improves throughput.

Embodiments described in greater detail herein may further be enhanced by leveraging deposition techniques and precursor formulation chemistries in order to tailor the polymeric structure of the responsive layer. That is, any of the responsive layers described herein may utilize deposition techniques, chemistries, and/or treatments similar to those described below. In an embodiment, the responsive layer may be tailored to improve dose to size (DtS) for exposure of the resist layer, and/or for controlling the reflow behavior of the responsive layer. In some embodiments, the use of one or more of low temperature, low power settings, and/or pulsing may lead to improved polymer networks within the responsive layer. More generally, this may lead to lightly cross-linked polymers with long linear CH₂ chains, which reduce DtS and improves LWR. This allows for improved release of H* species from the responsive layer that are able to diffuse into the overlying resist layer. This enhances the solubility switch by improving metal ligand removal rates. The longer linear chains allow for reflow at lower temperatures in order to allow for surface energy reduction that leads to improved LWR.

As noted herein, the responsive layer may be deposited with a dry deposition process. In a particular embodiment, the dry deposition process may be a PECVD process. The PECVD process may use any suitable plasma source, such as a capacitively coupled plasma (CCP), an inductively coupled plasma (ICP), a remote plasma source, or the like. When using a PECVD process, a low power plasma and low deposition temperature (e.g., less than 300° C., less than 250° C., or less than 100° C.) may be used. The use of such milder deposition conditions has shown (e.g., with a nuclear magnetic resonance (NMR) spectroscopy plot) to increase the distance between crosslinks as indicated by an increase in a peak with a chemical shift that is consistent with —CH₂— moieties. For example, an NMR spectroscopy plot of the responsive layer may show a higher mole fraction of sp3 aliphatic moieties than a mole fraction of sp2 aliphatic moieties. Additionally, the plasma may be pulsed. The pulsing may include an on-off cycle that is up to 1 second on and up to 1 second off, up to 5 seconds on and up to five seconds off, up to 10 seconds on and up to 10 second off, up to 30 seconds on and up to 30 seconds off, or any other duration. In some embodiments, the plasma on duration is equal to the plasma off duration for each cycle. In other embodiments, the plasma on duration is different than the plasma off duration. Pulsing the plasma in a PECVD deposition process may allow for better retention of the monomer structure in order to produce a linear polymer architecture.

In some embodiments, the precursor formulation used to deposit the responsive layer with such a deposition process may include one or more monomers that comprise carbon structures that contain one or more of hydrogen bonding, metal ligand interactions, van der waals interactions, hydrophobic effects, and/or dynamic covalent bonds (e.g., disulfides, oximes, imines, Michael-adducts, or diels-alder, etc.). For example, suitable monomers may include one or more of, N-[3-(dimethylamino) propyl]methacrylamide, 1-vinyl-2-pyrrolidinone, isobornyl methacrylate, norbornene, cyclohexyl methacrylate, styrene, vinylphenol, vinylpyridine, vinylimidazole, (2-Methylpropenyl) benzene, norbornenecarboxylic acid, propylene, propene, acetylene, octene, cyclooctene, cyclooctadiene, cycloalkene, cis-3-hexen-1-ol, isomers thereof, or any combination thereof. In some embodiments, the precursor formulation may further comprise a polymer inhibitor in addition to the monomer in the precursor formulation to enable delivery of the monomer to a chamber (e.g., the PECVD chamber) where polymerization occurs, while polymerization is prevented in the delivery vessel (e.g., an ampoule). That is, the precursor formulation may comprise a monomer mixture and an inhibitor in some embodiments. In an embodiment, the polymer inhibitor may be up to approximately 1.0 weight percent of the precursor formulation.

In an embodiment, the precursor formulation with the desired monomer is used to generate a polymeric species when deposited over the substrate within the chamber. In some embodiments, the polymeric species is linear. Though, embodiments may also include polymer structures that are a branched polymer, a catenated polymer, a comb-like polymer, a hyper-branched polymer, a cross-linked polymer, a dendrimer polymer, a dendron polymer, a block copolymer, a star polymer, a brush polymer, an AB₂ star polymer, a palm-tree ABₙ polymer, an H-shaped B₂AB₂ polymer, a dumbbell polymer, a ring block polymer, a star block ABₙ polymer, a coil-cycle-coil polymer, a star AₙBₙ polymer, a combination of any of the polymer structures, or the like. In some embodiments, a radical initiator (e.g., Ar, He, NH₃, H₂, or the like) may also be flown into the chamber with the precursor formulation in order to retain the monomer structure during deposition to minimize reaction of polymer chains after termination.

In addition to PECVD deposition, responsive layers with linear chains and low crosslinking may also be formed with a spin coating processes. For example, the polymeric material may be synthesized and formulated into a liquid. The liquid may then be applied to the substrate with a spin coating process. In some instances, the formulated polymer is solubilized using an organic solvent comprising one or more of propylene glycol methyl ether acetate (PGMEA), 4-methyl-2-pentanol, anisole, or the like. In some embodiments, the formulation may also include a surfactant to reduce surface tension of the solvent/polymer mixture. Decreasing the surface tension may allow for the ability to make thin coatings (e.g., approximately 100 nm or less). In some embodiments, the formulation may also include an adhesion promoter to enhance the adhesion between the responsive layer and the substrate. In the case of a spin coated film, a baking process may be used after deposition in order to remove residual solvent and/or to enable activation of the responsive layer by lightly cross-linking or reacting with other species.

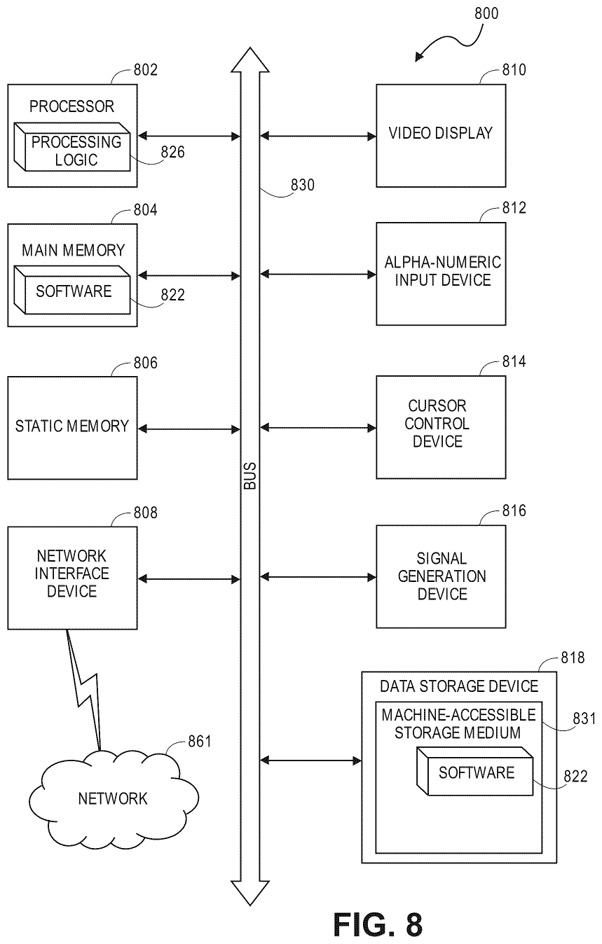

Referring now to FIG. 8, a block diagram of an exemplary computer system 800 of a processing tool is illustrated in accordance with an embodiment. In an embodiment, computer system 800 is coupled to and controls processing in the processing tool. Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 831 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 861 via the system network interface device 808. In an embodiment, the network interface device 808 may operate using RF coupling, optical coupling, acoustic coupling, or inductive coupling.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method for patterning a patterning stack, comprising:
forming the patterning stack over a substrate, wherein the patterning stack comprises a responsive layer and a resist layer over the responsive layer, and wherein the responsive layer is deposited with a plasma enhanced chemical vapor deposition (PECVD) process with a temperature less than 250° C.;
forming an opening in the resist layer;
transferring a pattern of the opening into the responsive layer, wherein the responsive layer has a first line width roughness (LWR); and
reflowing the responsive layer to form a reflown responsive layer, wherein the reflown responsive layer has a second LWR that is smaller than the first LWR.

2. The method of claim 1, wherein the PECVD process is a pulsed PECVD process.

3. The method of claim 1, wherein a precursor formulation for the PECVD process comprises monomers that comprise one or more of hydrogen bonding, metal ligand interactions, van der waals interactions, hydrophobic effects, and/or dynamic covalent bonds.

4. The method of claim 3, wherein the precursor formulation comprises one or more of N-[3-(dimethylamino) propyl]methacrylamide, 1-Vinyl-2-pyrrolidinone, isobornyl methacrylate, norbornene, cyclohexyl methacrylate, styrene, vinylphenol, vinylpyridine, vinylimidazole, (2-methylpropenyl) benzene, norbornenecarboxylic acid, propylene, propene, acetylene, octene, cyclooctene, cyclooctadiene, cycloalkene, cis-3-hexen-1-ol, or isomers thereof.

5. The method of claim 3, wherein the precursor formulation further comprises a polymer inhibitor.

6. The method of claim 1, wherein the responsive layer comprises a substantially linear polymeric architecture.

7. The method of claim 1, wherein the responsive layer comprises a low-k dielectric polymer.

8. The method of claim 1, wherein forming the opening in the resist layer comprises:
exposing a portion of the resist layer and the responsive layer to extreme ultraviolet (EUV) radiation, wherein the responsive layer generates reactive species in response to the EUV radiation, and wherein the reactive species diffuse into the resist layer and participates in a chemical reaction in the resist layer that provides a solubility switch to the portion of the resist layer; and
developing the resist layer after a solubility switch in the portion of the resist layer.

9. The method of claim 1, wherein the responsive layer comprises a polymer structure that is a branched polymer, a catenated polymer, a comb-like polymer, a hyper-branched polymer, a cross-linked polymer, a dendrimer polymer, a dendron polymer, a block copolymer, a star polymer, a brush polymer, an AB₂ star polymer, a palm-tree ABₙ polymer, an H-shaped B₂AB₂ polymer, a dumbbell polymer, a ring block polymer, a star block ABₙ polymer, a coil-cycle-coil polymer, a star AₙBₙ polymer, or a combination of any of the polymer structures.

10. The method of claim 1, wherein a radical initiator is used during the PECVD process.

11. A method for patterning a patterning stack, comprising:
forming the patterning stack over a substrate, wherein the patterning stack comprises a responsive layer and a resist layer over the responsive layer, and wherein the responsive layer is deposited with a spin coating process;
forming an opening in the resist layer;
transferring a pattern of the opening into the responsive layer, wherein the responsive layer has a first line width roughness (LWR); and
reflowing the responsive layer to form a reflown responsive layer, wherein the reflown responsive layer has a second LWR that is smaller than the first LWR.

12. The method of claim 11, wherein the spin coating process comprises dispensing a liquid polymer formulation onto the substrate.

13. The method of claim 12, wherein the liquid polymer formulation comprises a solubilized polymer in an organic solvent.

14. The method of claim 13, wherein the organic solvent comprises one or more of propylene glycol methyl ether acetate (PGMEA), 4-methyl-2-pentanol, or anisole.

15. The method of claim 12, wherein the liquid polymer formulation comprises a surfactant.

16. The method of claim 12, wherein the liquid polymer formulation comprises an adhesion promoter.

17. The method of claim 11, wherein the responsive layer comprises one or more of N-[3-(dimethylamino)propyl]methacrylamide, 1-Vinyl-2-pyrrolidinone, isobornyl methacrylate, norbornene, cyclohexyl methacrylate, styrene, vinylphenol, vinylpyridine, vinylimidazole, (2-methylpropenyl) benzene, norbornenecarboxylic acid, propylene, propene, acetylene, octene, cyclooctene, cyclooctadiene, cycloalkene, cis-3-hexen-1-ol, or isomers thereof.

18. The method of claim 11, wherein the responsive layer has a higher mole fraction of sp3 aliphatic moieties than sp2 aliphatic moieties.

19. The method of claim 11, wherein the spin coating process further comprises baking the responsive layer.

20. The method of claim 11, wherein the resist layer is a metal-oxide resist material.
